(19) United States
(12) Patent Application Publication
(10) Pub. No.: US 2024/0162395 A1
(43) Pub. Date: May 16, 2024

(54) DISPLAY DEVICE

(71) Applicant: LG DISPLAY CO., LTD., SEOUL (KR)

(72) Inventors: SeongKyong PARK, Gyeonggi-do (KR); MoonBong SONG, Gyeonggi-do (KR); Yanghwan KIM, Gyeonggi-do (KR)

(73) Assignee: LG DISPLAY CO., LTD., SEOUL (KR)

(21) Appl. No.: 18/387,182

(22) Filed: Nov. 6, 2023

(30) Foreign Application Priority Data
Nov. 11, 2022 (KR) 10-2022-0150460

(51) Int. Cl. H01L 33/58; H01L 33/38; H01L 33/54; H01L 33/62

(52) U.S. Cl. CPC H01L 33/58; H01L 33/38; H01L 33/54; H01L 33/62

(57) ABSTRACT

A display device includes a substrate with a plurality of subpixels, at least one thin film transistor and at least one light emitting diode formed in each of the plurality of sub pixels on the substrate, and a molding portion formed on each of the light emitting diodes, wherein the thin film transistor and the light emitting diode are electrically connected to each other, and the molding portion includes a scattering layer for scattering light and a lens layer formed on the scattering layer.

### CROSS-REFERENCE TO RELATED APPLICATION

This application claims priority from Korean Patent Application No. 10-2022-0150460, filed on Nov. 11, 2022, which is hereby incorporated by reference in its entirety.

### BACKGROUND

### Field of the Disclosure

The present disclosure relates to a display device, and more particularly, to a display device using a light emitting diode.

### Description of the Background

A display device is widely used as a display screen of a laptop computer, a tablet computer, a smart phone, a portable display device, and a portable information device display device in addition to a display screen of a television or a monitor. A liquid crystal display device and an organic light emitting display device display an image by the use of thin film transistor serving as a switching element. The liquid crystal display device displays an image by the use of light irradiated from a backlight unit disposed under a liquid crystal display panel because the liquid crystal display device is not in a self-luminous manner. Since the liquid crystal display device has the backlight unit, there is a limitation in design, and luminance and response speed may be reduced. Since the organic light emitting display device includes an organic material, the organic light emitting display device is vulnerable to moisture, whereby reliability and lifespan thereof may be deteriorated.

Recently, research and development of a light emitting diode display device using a micro light emitting diode has been conducted, and the light emitting diode display device has high quality and high reliability, whereby it is spotlighted as a next generation display device. Particularly, research is performed to further improve the light efficiency of the light emitting diode display device.

### SUMMARY

Accordingly, the present disclosure to provide a display device with an improved light efficiency.

In accordance with an aspect of the present disclosure, the above and other features may be accomplished by the provision of a display device comprising a substrate with a plurality of subpixels, and at least one thin film transistor and at least one light emitting diode formed in each of the plurality of sub pixels on the substrate, and a molding portion formed on each of the light emitting diodes, wherein the thin film transistor and the light emitting diode are electrically connected to each other, and the molding portion includes a scattering layer for scattering light and a lens layer formed on the scattering layer.

In accordance with another aspect of the present disclosure, the above and other objects may be accomplished by the provision of a display device comprising: a substrate with a plurality of subpixels; at least one light emitting diode formed in each of the plurality of subpixels; and a molding portion formed on each of the light emitting diodes, wherein the molding portion includes a scattering layer for scattering light and a lens layer formed on the scattering layer, and the lens layer include a plurality of optical lenses which are arranged to extend along a first direction, are spaced apart from each other along a second direction perpendicular to the first direction, and are linearly formed.

In addition to the effects of the present disclosure as mentioned above, additional advantages and features of the present disclosure will be clearly understood by those skilled in the art from the above description of the present disclosure.

### BRIEF DESCRIPTION OF THE DRAWINGS

The above and other features and advantages of the present disclosure will be more clearly understood from the following detailed description taken in conjunction with the accompanying drawings, in which:

FIG. 1 is a plan view illustrating a display device according to an aspect of the present disclosure;

FIG. 2 is a cross-sectional view illustrating a display device according to aspect 1-1 of the present disclosure;

FIG. 3 is a cross-sectional view illustrating a display device according to aspect 1-2 of the present disclosure;

FIG. 4 is a cross-sectional view illustrating a display device according to aspect 1-3 of the present disclosure;

FIG. 5 is a cross-sectional view illustrating a display device according to aspect 2-1 of the present disclosure;

FIG. 6 is a cross-sectional view illustrating a display device according to aspect 2-2 of the present disclosure;

FIG. 7 is a cross-sectional view illustrating a display device according to aspect 2-3 of the present disclosure;

FIG. 8 is a cross-sectional view illustrating a display device according to aspect 3-1 of the present disclosure;

FIG. 9 is a cross-sectional view illustrating a display device according to aspect 3-2 of the present disclosure;

FIG. 10 is a cross-sectional view illustrating a display device according to aspect 3-3 of the present disclosure;

FIG. 11 is a cross-sectional view illustrating a display device according to aspect 4-1 of the present disclosure;

FIG. 12 is a cross-sectional view illustrating a display device according to the aspect 4-2 of the present disclosure;

FIG. 13 is a cross-sectional view illustrating a display device according to aspect 4-3 of the present disclosure;

FIG. 14 is a cross-sectional view illustrating a display device according to a fifth aspect of the present disclosure;

FIG. 15 is a cross-sectional view along A-A′ of a light emitting diode and a molding portion in the display device according to the fifth aspect of the present disclosure; and

FIG. 16 is a cross-sectional view along B-B′ of a light emitting diode and a molding portion in the display device according to the fifth aspect of the present disclosure.

### DETAILED DESCRIPTION

Advantages and features of the present disclosure, and implementation methods thereof will be clarified through the following aspects, described with reference to the accompanying drawings. The present disclosure may, however, be embodied in different forms and should not be construed as being limited to the aspects set forth herein. Rather, these aspects are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing aspects of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various aspects of the present disclosure may be partially or overall coupled to or combined with each other, and may be variously inter-operated with each other and driven technically as those skilled in the art may sufficiently understand. The aspects of the present disclosure may be carried out independently from each other, or may be carried out together in a co-dependent relationship.

Hereinafter, a display device according to the present disclosure will be described with reference to the accompanying drawings.

FIG. 1 is a plan view illustrating a display device according to one aspect of the present disclosure.

Referring to FIG. 1, a display device 10 according to an aspect of the present disclosure may include a display area AA in which an image is displayed and a non-display area NA surrounding the display area AA. A light emitting element and a driving element for driving the light emitting element may be formed in the display area AA. Also, the non-display area NA is an area in which an image is not displayed, and a control circuit connected to the elements arranged in the display area AA may be formed.

FIG. 1 discloses that the display device 10 includes the display area AA and the non-display area NA, but not limited thereto. For example, the display device 10 may not include the non-display area NA.

A plurality of subpixels P may be formed in the display area AA. Each of the plurality of subpixels P may emit red, green, and blue light, but not limited thereto. Each of the plurality of subpixels P may include at least one driving element or more and at least one light emitting element or more. In addition, each of the driving element and the light emitting element may be connected to a driving portion such as a gate control circuit and a data control circuit through a wiring such as a gate line GL and a data line DL. In addition, the driving element and the light emitting element may be a thin film transistor and a light emitting diode.

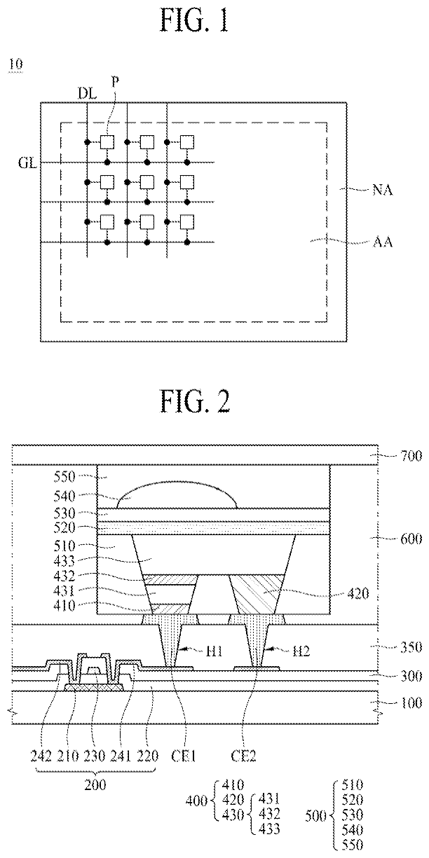

FIGS. 2 to 4 are cross-sectional views illustrating a display device according to the aspects 1-1 to 1-3 of the present disclosure. FIGS. 2 to 4 show one subpixel.

Referring to FIG. 2 to FIG. 4, the display device according to the aspects 1-1 to 1-3 of the present disclosure may include a substrate 100, a thin film transistor 200, an insulating interlayer 300, a planarization layer 350, and a light emitting element L including a light emitting diode 400 and a molding portion 500.

FIGS. 2 to 4 disclose that one subpixel includes one thin film transistor 200 and one light emitting element L, but not limited thereto. For example, one subpixel may include one thin film transistor 200 and a plurality of light emitting elements L, and one thin film transistor 200 may drive all of the plurality of light emitting elements L. Alternatively, one subpixel may include a plurality of thin film transistors 200 and a plurality of light emitting elements L, and the plurality of thin film transistors 200 may drive each of the light emitting elements L corresponding to each of the plurality of thin film transistors 200.

The substrate 100 may be formed of glass or plastic, but not limited thereto. The display device according to one aspect of the present disclosure may be configured by a top emission method in which light is emitted toward an upper portion. Therefore, an opaque material as well as a transparent material may be used as a material for the substrate 100.

The thin film transistor 200 may be formed on the substrate 100. The thin film transistor 200 may include a semiconductor layer 210, a gate insulating layer 220, a gate electrode 230, a source electrode 241, and a drain electrode 242.

The semiconductor layer 210 of the thin film transistor 200 may be formed on the substrate 100. The semiconductor layer 210 may include polysilicon semiconductor or oxide semiconductor. When the semiconductor layer 210 includes oxide semiconductor, the semiconductor layer 210 may include one of indium-gallium-zinc-oxide (IGZO), indium-zinc-oxide (IZO), indium-gallium-tin-oxide (IGTO), and indium-gallium-oxide (IGO).

The gate insulating layer 220 of the thin film transistor 200 is formed on the semiconductor layer 210 and is configured to insulate the gate electrode 230 from the semiconductor layer 210. The gate insulating layer 220 of the thin film transistor 200 may be composed of a single layer of silicon nitride (SiNx) or silicon oxide (SiOx) or multilayers thereof.

The gate electrode 230 of the thin film transistor 200 may be formed on the gate insulating layer 220. The gate electrode 230 may be formed on the gate insulating layer 220 and is configured to overlap with a channel region of the semiconductor layer 210.

The insulating interlayer 300 may be formed on the gate insulating layer 220 and the gate electrode 230 of the thin film transistor 200. The insulating interlayer 300 may be formed of an organic insulating material such as acryl resin, epoxy resin, phenolic resin, polyamide resin, and polyimide resin.

A contact hole for exposing the semiconductor layer 210 of the thin film transistor 200 may be formed in the gate insulating layer 220 of the thin film transistor 200 and the insulating interlayer 300.

The source electrode 241 and the drain electrode 242 of the thin film transistor 200 may be formed on the insulating interlayer 300 while the source electrode 241 and the drain electrode 242 face each other. In addition, each of the source electrode 241 and the drain electrode 242 of the thin film transistor 200 may be connected to the semiconductor layer 210 through each contact hole formed in the gate insulating layer 220 and the insulating interlayer 300, respectively.

Although not shown in FIGS. 2 to 4, the gate line GL may be formed on the same layer as the gate electrode 230. The gate line GL may be formed of the same material as the gate electrode 230, and the data line DL may also be formed of the same material as the gate line GL.

A common line CL may be formed on the insulating interlayer 300. The common line CL is a wiring for applying a common voltage to the light emitting diode 400 and may be spaced apart from the gate line GL or the data line DL. Also, the common line CL may extend in the same direction as the gate line GL or the data line DL. The common line CL may be formed of the same material as the source electrode 241 and the drain electrode 242, but not limited thereto.

The planarization layer 350 may be formed on the insulating interlayer 300. The planarization layer 350 may compensate for a step difference caused by the thin film transistor 200, the common line CL, and the contact holes. The planarization layer 350 may be made of an inorganic insulating material or an organic insulating material. Alternatively, the planarization layer 350 may be formed by stacking a layer of the organic insulating material and a layer of the inorganic insulating material.

A first contact hole H1 for exposing the source electrode 241 of the thin film transistor 200 and a second contact hole H2 for exposing the common line CL may be formed in the planarization layer 350. A first connection electrode CE1 is formed on the planarization layer 350 and may be electrically connected to the source electrode 241 of the thin film transistor 200 through the first contact hole H1. A second connection electrode CE2 is formed on the planarization layer 350 and may be electrically connected to the common line CL through the second contact hole H2.

Each of the first and second connection electrodes CE1 and CE2 may include a metal material such as Au, W, Pt, Si, Ir, Ag, Cu, Ni, Ti, and Cr, or an alloy thereof. Alternatively, each of the first and second connection electrodes CE1 and CE2 may include a transparent conductive material such as indium tin oxide ITO or indium zinc oxide IZO.

The light emitting element L may be formed on the planarization layer 350. The light emitting element L may include the light emitting diode 400 for emitting light and the molding portion 500 for protecting the light emitting diode 400.

The light emitting diode 400 may be formed on the planarization layer 350. The light emitting diode 400 may include a first electrode 410, a second electrode 420, and a light emitting layer 430.

The first electrode 410 may be electrically connected to the source electrode 241 of the thin film transistor 200 through the first connection electrode CE1. In addition, the second electrode 420 may be electrically connected to the common line CL through the second connection electrode CE2. Accordingly, different voltage levels respectively applied to the source electrode 241 of the thin film transistor 200 and the common line CL are transmitted to the first and second electrodes 410 and 420 through the first and second connection electrodes CE1 and CE2, whereby the light emitting diode 400 may emit light.

Each of the first and second electrodes 410 and 420 may include a metal material such as Au, W, Pt, Si, Ir, Ag, Cu, Ni, Ti, and Cr, or an alloy thereof. Alternatively, each of the first and second electrodes 410 and 420 may include a transparent conductive material such as indium tin oxide (ITO) and indium zinc oxide (IZO).

The light emitting layer 430 may emit light according to a recombination of electrons and holes according to a current flowing between the first electrode 410 and the second electrode 420. The light emitting layer 430 may include a first semiconductor layer 431, an active layer 432, and a second semiconductor layer 433.

The first semiconductor layer 431 is formed on the first electrode 410 and is configured to provide holes to the active layer 432. The first semiconductor layer 431 may be made of a p-GaN-based semiconductor material such as GaN, AlGaN, InGaN, and AlInGaN. Also, impurities used for doping of the first semiconductor layer 431 may be Mg, Zn, Be, or the like.

The active layer 432 is formed on the first semiconductor layer 431. The active layer 432 may have a multi-quantum well (MQW) structure having a well layer and a barrier layer having a band gap higher than that of the well layer. For example, the active layer 432 may have a multi-quantum well structure of InGaN/GaN, but not limited thereto.

The second semiconductor layer 433 is formed on the active layer 432 and is configured to provide electrons to the active layer 432. The second semiconductor layer 433 may be made of an n-GaN-based semiconductor material such as GaN, AlGaN, InGaN, and AlInGaN. Also, impurities used for doping of the second semiconductor layer 433 may be Si, Ge, Se, Te, C, or the like.

The molding portion 500 may be formed on the light emitting diode 400. The molding portion 500 may include a first protective layer 510, a scattering layer 520, a light guide layer 530, a lens layer 540, and a second protective layer 550.

The first protective layer 510 may be formed to surround the light emitting diode 400. That is, the first protective layer 510 may be formed to cover a side surface and a lower surface of the light emitting diode 400. The upper surface of the first protective layer 510 may be formed on the same layer as the upper surface of the second semiconductor layer 433 of the light emitting diode 400. Referring to FIGS. 2 to 4, the first protective layer 510 may not be formed on the upper surface of the second semiconductor layer 433, but not limited thereto. That is, the first protective layer 510 may be formed to cover the upper surface of the second semiconductor layer 433. In this case, the upper surface of the first protective layer 510 may be flat.

The first protective layer 510 may be formed such that a portion of each of the first and second electrodes 410 and 420 is exposed so that each of the first and second electrodes 410 and 420 of the light emitting diode 400 may be in contact with the first and second connection electrodes CE1 and CE2.

The first protective layer 510 may comprise an inorganic insulating material such as silicon oxide (SiOx) and silicon nitride (SiNx). Alternatively, the first protective layer 510 may include an organic insulating material such as acryl resin, epoxy resin, phenolic resin, polyamide resin, and polyimide resin.

The scattering layer 520 may be formed on the second semiconductor layer 433 of the light emitting diode 400 and the first protective layer 510. The upper surface of the scattering layer 520 may be formed to be flat. Also, the area of the lower surface of the scattering layer 520 may be the same as the area of the upper surface of the second semiconductor layer 433 and the first protective layer 510.

The scattering layer 520 may include a scattering material and an insulating material. The scattering material is uniformly dispersed in the insulating material and may scatter incident light. Typically, due to a P/N electrode structure of the light emitting diode 400, the light emitting diode 400 may have asymmetry in luminance of left and right orientation angles. However, since the scattering layer 520 is formed on the light emitting diode 400, light generated by the light emitting diode 400 may pass through the scattering layer 520 and may be uniformly emitted. Accordingly, it is possible to overcome the asymmetry of luminance caused by the light emitting diode 400.

The insulating material may be an inorganic insulating material such as silicon oxide (SiOx) and silicon nitride (SiNx). Alternatively, the insulating material may be an organic insulating material such as acryl resin, epoxy resin, phenolic resin, polyamide resin, and polyimide resin. In addition, the scattering material may be a metal material or an oxide material such as silver (Ag), aluminum (Al), and titanium oxide (TiO₂), but not limited thereto.

The light guide layer 530 may be formed on the scattering layer 520. The upper surface of the light guide layer 530 may be formed to be flat. In addition, the area of the lower surface of the light guide layer 530 may be the same as the area of the upper surface of the scattering layer 520.

To minimize a loss of light passing through the light guide layer 530, the light guide layer 530 may comprise a light transmitting resin such as acryl resin, epoxy resin, phenolic resin, polyamide resin, and polyimide resin.

On the light guide layer 530, the lens layer 540 may be formed on a region overlapping with the active layer 432 of the light emitting diode 400. The lens layer 540 may include at least one optical lens and may refract light incident at an angle different from a front surface of the display device so that the incident light faces the front surface of the display device. Accordingly, a path of light may be changed so that light directed toward a side surface of the display device faces a front direction of the display device. Therefore, a light extraction efficiency of the light emitting diode 400 may be improved by increasing the amount of light from the light emitting diode 400 to the front surface of the display device, as compared to a related art structure.

In this case, a distance between the light emitting diode 400 and the lens layer 540 may be adjusted by adjusting a thickness of the light guide layer 530. That is, according as the distance at which light emitted from the light emitting diode 400 is incident to the lens layer 540 is adjusted, it is possible to improve a light collection effect and light extraction efficiency of the lens layer 540. For example, when a diameter of the optical lens formed in the lens layer 540 is 30 μm or more, and 45 μm or less, and a height of the optical lens is 9 the thickness of the light guide layer 530 may be 10 μm or more, and 17 μm or less, but not limited thereto.

A refractive index of the lens layer 540 may be greater than a refractive index of the light guide layer 530. Accordingly, the light passing through the scattering layer 520 may not be affected by the light guide layer 530, and may be refracted toward the front surface of the display device by the lens layer 540. For example, the refractive index of the light guide layer 530 may be 1.55 or less, and the refractive index of the lens layer 540 may be 1.6 or more, but not limited thereto.

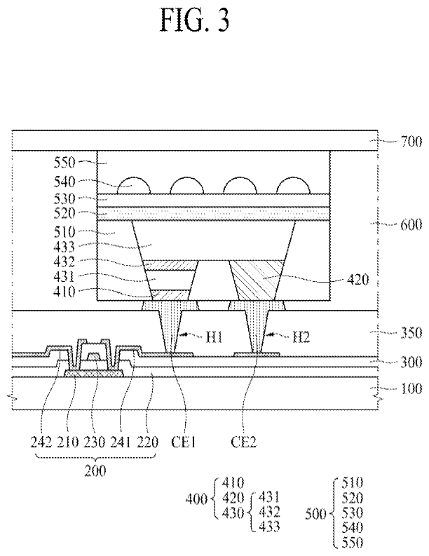

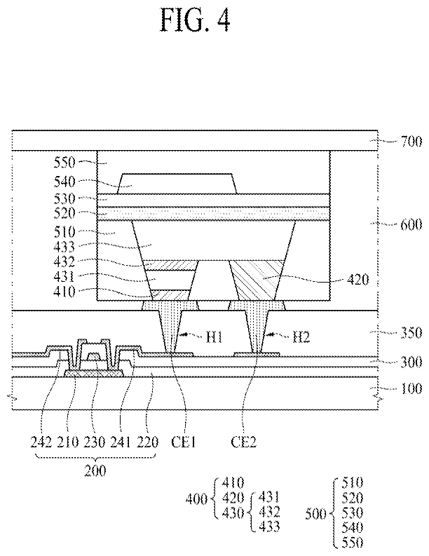

Referring to FIG. 2, the lens layer 540 may include one optical lens having a convex hemispherical shape, but not limited thereto. For example, referring to FIG. 3, the lens layer 540 may include a plurality of optical lenses having a convex hemispherical shape. In this case, some of the plurality of optical lenses may overlap with the active layer 432 of the light emitting diode 400. Alternatively, referring to FIG. 4, the lens layer 540 may include one optical lens, and the cross section of the lens layer 540 may have a trapezoidal shape. That is, the upper surface and the side surface of the optical lens are formed in a plane, and the side surface of the optical lens may be formed to form an acute angle with the upper surface of the light guide layer 530.

The second protective layer 550 may be formed on the light guide layer 530 and is configured to cover the light guide layer 530 and the lens layer 540. The second protective layer 550 may stably fix the lens layer 540 on the light guide layer 530 and may prevent the lens layer 540 from being damaged by an external impact. Also, the upper surface of the second protective layer 550 may be formed to be flat.

To minimize a loss of light passing through the second protective layer 550, the second protective layer 550 may comprise a light transmitting resin such as acryl resin, epoxy resin, phenolic resin, polyamide resin, and polyimide resin.

Meanwhile, a related art discloses a structure including a light emitting diode formed on a substrate and an optical lens formed independently on the light emitting diode. In this case, an error occurs in a process of forming the light emitting diode on the substrate, so that the light emitting diode may not be formed at a position designed on the substrate. In this case, non-uniformity of a viewing angle may be increased according to the formation position of the light emitting diode. Also, since a process of forming the optical lens independently on the light emitting diode is performed, an error may occur in an arrangement relationship between the light emitting diode and the optical lens. Accordingly, the amount of light from the light emitting diode toward the optical lens is reduced, thereby reducing the light collection efficiency of the lens.

On the other hand, the present disclosure illustrates the light emitting element L in which the molding portion 500 including the lens layer 540 and the light emitting diode 400 are integrated. Accordingly, as compared to the related art, the range in which the lens layer 540 is formed on the light emitting diode 400 is limited, thereby minimizing the error of arrangement relationship between the light emitting diode 400 and the lens layer 540. Therefore, as compared to the related art, the present disclosure increases the efficiency of the lens layer 540 and enables the improvement of viewing angle according to the formation position of the light emitting diode 400.

The encapsulation layer 600 may be formed on the planarization layer 350 and may be provided to surround the side surface of the light emitting element L. The encapsulation layer 600 may enable a stable fixation in position of the light emitting element L and may prevent damages caused by an external impact. Also, the upper surface of the encapsulation layer 600 may be formed on the same layer as the upper surface of the second protective layer 550. Alternatively, the encapsulation layer 600 may be formed to cover both the upper surface and the side surface of the light emitting element L.

The encapsulation layer 600 may be formed of an inorganic insulating material such as silicon oxide SiOx and silicon nitride SiNx. Alternatively, the encapsulation layer 600 may include an organic insulating material such as acryl resin, epoxy resin, phenolic resin, polyamide resin, and polyimide resin.

The protective film 700 is formed on the encapsulation layer 600, thereby preventing an introduction of external light and minimizing a reduction of luminance.

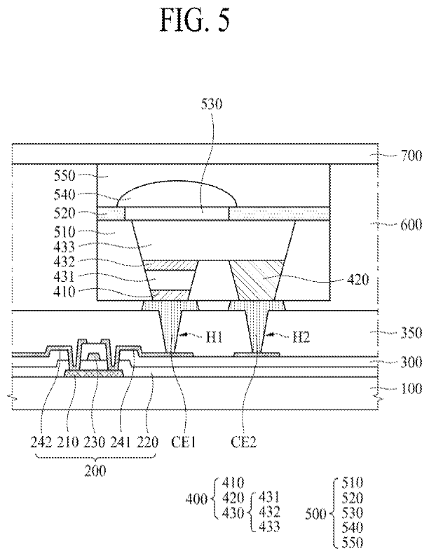

FIGS. 5 to 7 are cross-sectional views illustrating a display device according to the aspects 2-1 to 2-3 of the present disclosure. FIGS. 5 to 7 show one subpixel.

A display device according to FIGS. 5 to 7 has the substantially same structure as that of the display device according to FIGS. 2 to 4 except for a structure of a molding portion 500. Therefore, the same elements as those of the display device shown in FIGS. 2 to 4 are denoted by the same reference numerals, and repeated descriptions thereof are omitted.

Referring to FIGS. 5 to 7, a molding portion 500 may be formed on a light emitting diode 400. The molding portion 500 may include a first protective layer 510, a scattering layer 520, a light guide layer 530, a lens layer 540, and a second protective layer 550.

As described above with reference to FIGS. 2 to 4, the first protective layer 510 may be formed to cover a side surface and a lower surface of the light emitting diode 400. Also, an upper surface of the first protective layer 510 may be formed on the same layer as an upper surface of a second semiconductor layer 433 of the light emitting diode 400.

The scattering layer 520 and the light guide layer 530 may be formed on the second semiconductor layer 433 of the light emitting diode 400 and the first protective layer 510. The scattering layer 520 and the light guide layer 530 may be formed as one single layer. Through recombination of holes and electrons provided from the first and second semiconductor layers 431 and 433, the light emitting diode 400 may generate light in an active layer 432. Accordingly, a light extraction efficiency of the light emitting diode 400 may be maximized by forming the light guide layer 530 and the lens layer 540 in a region overlapping with the active layer 432.

The scattering layer 520 may be formed in an area surrounding the light guide layer 530. Accordingly, the scattering layer 520 may scatter the light emitted to the outside of the light guide layer 530, thereby increasing the amount of light incident on the lens layer 540. Therefore, the light efficiency of the display device may be improved through the scattering layer 520. Also, the lens layer 540 may extend on the light guide layer 530 and overlap with the light guide layer 530, and may also overlap with the scattering layer 520.

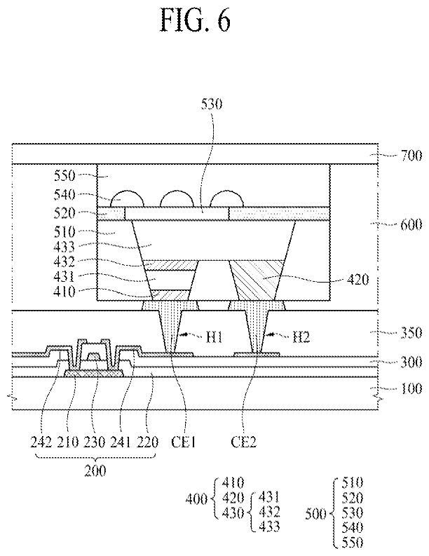

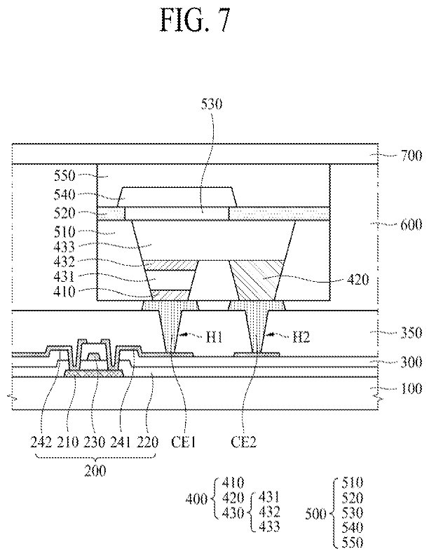

Referring to FIG. 5, the lens layer 540 may include one optical lens having a convex hemispherical shape, but not limited thereto. For example, referring to FIG. 6, the lens layer 540 may include a plurality of optical lenses having a convex hemispherical shape. In this case, some of the plurality of optical lenses may overlap with the active layer 432 of the light emitting diode 400. Alternatively, referring to FIG. 7, the lens layer 540 may include one optical lens, and may have a trapezoidal cross section. That is, upper and side surfaces of the optical lens are formed in a plane, and the side surface of the optical lens may be formed to form an acute angle with an upper surface of the light guide layer 530.

Aspects 3-1 to 3-3

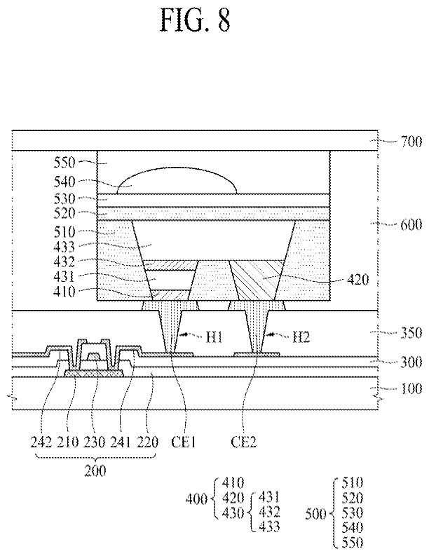

FIGS. 8 to 10 are cross-sectional views illustrating a display device according to the aspects 3-1 to 3-3 of the present disclosure. FIGS. 8 to 10 show one subpixel.

A display device according to FIGS. 8 to 10 has the substantially same structure as that of the display device according to FIGS. 2 to 4 except for a structure of a molding portion 500. Therefore, the same elements as those of the display device shown in FIGS. 2 to 4 are denoted by the same reference numerals, and repeated descriptions thereof are omitted.

Referring to FIGS. 8 to 10, a molding portion 500 may be formed on a light emitting diode 400. The molding portion 500 may include a first protective layer 510, a scattering layer 520, a light guide layer 530, a lens layer 540, and a second protective layer 550.

As described above with reference to FIGS. 2 to 4, the first protective layer 510 may be formed to cover a side surface and a lower surface of the light emitting diode 400. In this case, the first protective layer 510 may include a scattering material and an insulating material. The scattering material is uniformly dispersed in the insulating material and may scatter incident light. Accordingly, the first protective layer 510 scatters light emitted to the side surface or lower surface of the light emitting diode 400, thereby increasing the amount of light incident on the light guide layer 530 and the lens layer 540. Therefore, the light extraction efficiency of the light emitting diode 400 may be improved through the first protective layer 510 including the scattering material.

The insulating material may be an inorganic insulating material such as silicon oxide SiOx and silicon nitride SiNx. Alternatively, the insulating material may be an organic insulating material such as acryl resin, epoxy resin, phenolic resin, polyamide resin, and polyimide resin. In addition, the scattering material may be a metal material or an oxide material such as silver Ag, aluminum Al, and titanium oxide TiO₂, but not limited thereto.

As described above with reference to FIGS. 2 to 4, the scattering layer 520 may be formed on a second semiconductor layer 433 of the light emitting diode 400 and the first protective layer 510. Also, the scattering layer 520 may include a scattering material and an insulating material. The scattering material and the insulating material for forming the scattering layer 520 may be the same as the scattering material and the insulating material for the first protective layer 510. In this case, the first protective layer 510 and the scattering layer 520 may be seen as one layer and may be formed through one process, to thereby simplify a manufacturing process.

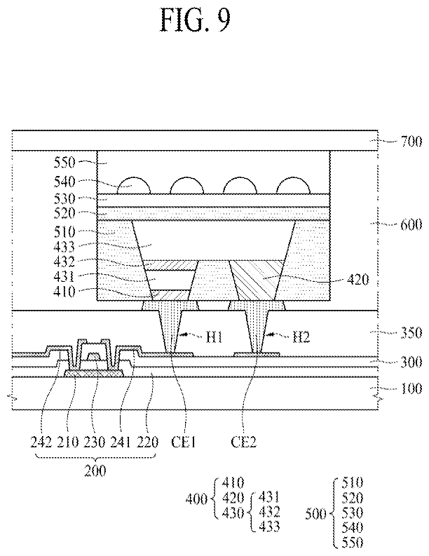

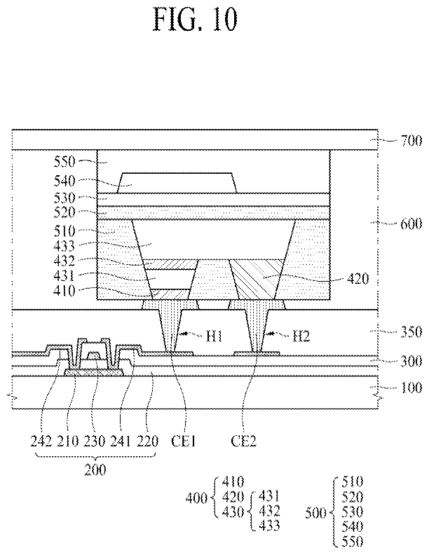

Referring to FIG. 8, the lens layer 540 may include one optical lens having a convex hemispherical shape, but not limited thereto. For example, referring to FIG. 9, the lens layer 540 may include a plurality of optical lenses having a convex hemispherical shape. In this case, some of the plurality of optical lenses may overlap with the active layer 432 of the light emitting diode 400. Alternatively, referring to FIG. 10, the lens layer 540 includes one optical lens, and the cross section of the lens layer 540 may have a trapezoidal shape. That is, upper and side surfaces of the optical lens are formed in a plane, and the side surface of the optical lens may be formed to form an acute angle with an upper surface of the light guide layer 530.

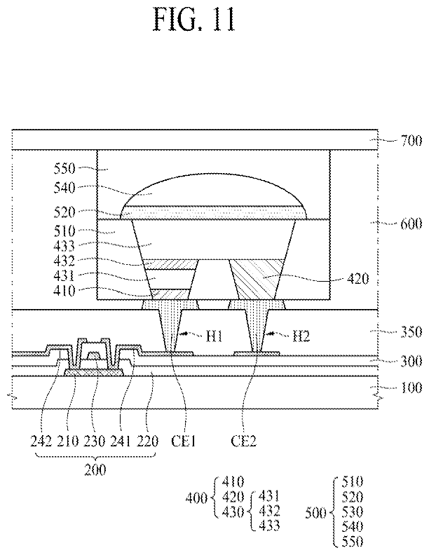

FIGS. 11 to 13 are cross-sectional views illustrating a display device according to the aspects 4-1 to 4-3 of the present disclosure. FIGS. 11 to 13 show one subpixel.

A display device according to FIGS. 11 to 13 has the substantially same structure as the display device according to FIGS. 2 to 4 except for a structure of a molding portion 500. Therefore, the same elements as those of the display device shown in FIGS. 2 to 4 are denoted by the same reference numerals, and repeated descriptions thereof are omitted.

Referring to FIGS. 11 to 13, a molding portion 500 may be formed on a light emitting diode 400. The molding portion 500 may include a first protective layer 510, a scattering layer 520, a lens layer 540, and a second protective layer 550.

As described above with reference to FIGS. 2 to 4, the first protective layer 510 may be formed to cover a side surface and a lower surface of the light emitting diode 400. Also, the upper surface of the first protective layer 510 may be formed on the same layer as an upper surface of a second semiconductor layer 433 of the light emitting diode 400.

The scattering layer 520 and the lens layer 540 may be formed on the second semiconductor layer 433 of the light emitting diode 400 and the first protective layer 510. In this case, the scattering layer 520 may be formed inside an optical lens formed in the lens layer 540 and may be integrated with the lens layer 540. That is, a lower surface of the scattering layer 520 may be in contact with the second semiconductor layer 433 and the first protective layer 510, and an upper surface of the scattering layer 520 may be in contact with the optical lens. In addition, a side surface of the scattering layer 520 may be formed along a shape of a side surface of the optical lens and may have the same curvature as the side surface of the optical lens. Thus, according as the lens layer 540 including the scattering layer 520 is formed, most of the light scattered from the scattering layer 520 may be directed to a front surface of the display device through the lens layer 540. Therefore, a light extraction efficiency of the light emitting diode 400 may be maximized and a manufacturing process of the display device may be simplified.

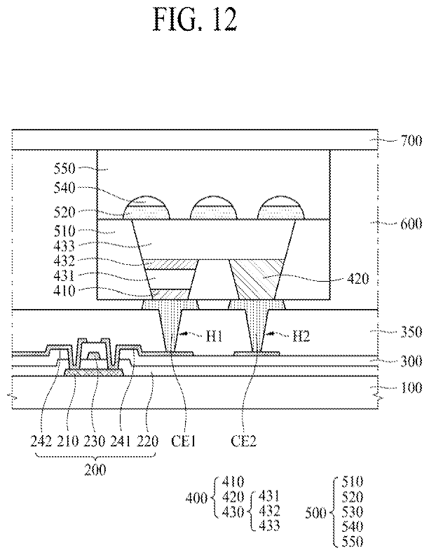

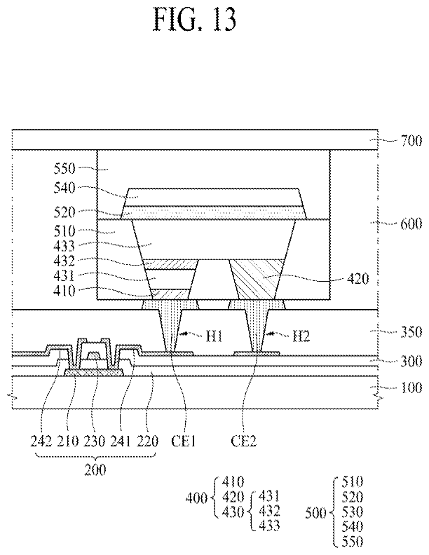

Referring to FIG. 11, the lens layer 540 may include one optical lens having a convex hemispherical shape, but not limited thereto. For example, referring to FIG. 12, the lens layer 540 may include a plurality of optical lenses having a convex hemispherical shape. In this case, some of the plurality of optical lenses may overlap with an active layer 432 of the light emitting diode 400. Also, the scattering layer 520 may be formed inside each of the plurality of optical lenses. Alternatively, referring to FIG. 13, the lens layer 540 may include one optical lens, and may have a trapezoidal cross section. That is, the upper surface and the side surface of the optical lens may be flat, and the side surface of the optical lens may be provided to form an acute angle with an upper surface of the first protective layer 510. In this case, the side surface of the scattering layer 520 may be formed to be flat and may be provided to form an acute angle with the upper surface of the first protective layer 510.

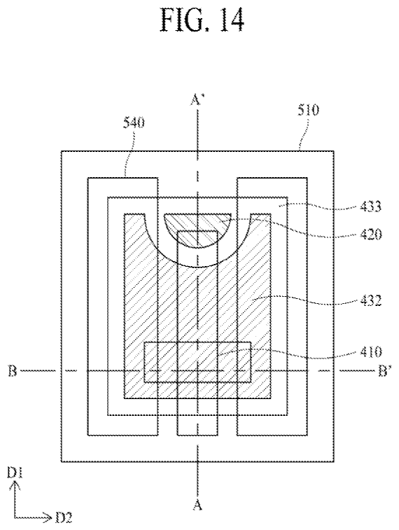

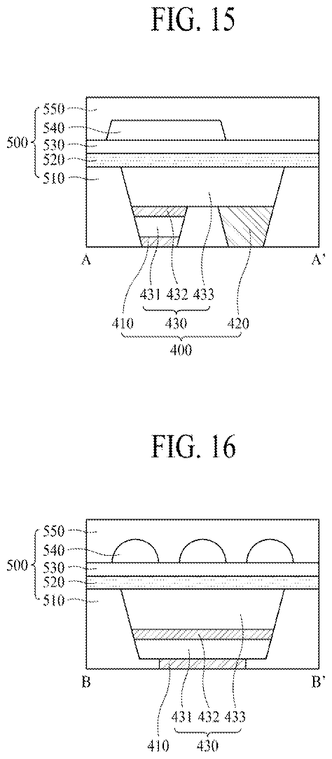

FIG. 14 is a plan view illustrating a light emitting diode 400 and a molding portion 500 in a display device according to a fifth aspect of the present disclosure. FIG. 15 is a cross-sectional view along A-A′ of the light emitting diode 400 and the molding portion 500 in the display device according to the fifth aspect of the present disclosure, and FIG. 16 is a cross-sectional view along B-B′ of the light emitting diode 400 and the molding portion 500 in the display device according to the fifth aspect of the present disclosure. FIGS. 14 to 16 show one light emitting diode 400 and molding portion 500.

A display device according to FIGS. 14 to 16 have the substantially same structure as those of the display device according to FIGS. 2 to 4 except for the structure of the molding portion 500. Therefore, the same elements as those of the display device shown in FIGS. 2 to 4 are denoted by the same reference numerals, and repeated descriptions thereof are omitted.

Referring to FIGS. 14 to 16, the molding portion 500 may be formed on the light emitting diode 400. The molding portion 500 may include a first protective layer 510, a scattering layer 520, a light guide layer 530, a lens layer 540, and a second protective layer 550.

As described above with reference to FIGS. 2 to 4, the first protective layer 510 may be formed to cover a side surface and a lower surface of the light emitting diode 400. Also, the scattering layer 520 may be formed on a second semiconductor layer 433 of the light emitting diode 400 and the first protective layer 510, and the light guide layer 530 may be formed on the scattering layer 520. On the light guide player 530, the lens layer 540 may be formed on a region overlapping with an active layer 432 of the light emitting diode 400.

Referring to FIG. 14, first and second electrodes 410 and 420 may be spaced apart from each other in a first direction D1. Also, the lens layer 540 may include a plurality of optical lenses arranged to be spaced apart from each other along a second direction D2 perpendicular to the first direction D1. Each of the plurality of optical lenses may extend along the first direction D1 and may be linearly formed. That is, the lens layer 540 may include the plurality of optical lenses formed in a tunnel shape.

In this case, some of the plurality of optical lenses may be formed to overlap with both ends of the active layer 432. That is, among the plurality of optical lenses, two optical lenses disposed on the periphery may be formed to cover each of both ends of the active layer 432. Accordingly, the light emitted from the side surface of the light emitting diode 400 may be refracted toward a front surface of the display device. Therefore, a light extraction efficiency of the light emitting diode 400 may be maximized.

Through recombination of holes and electrons provided from the first and second semiconductor layers 431 and 433, the light emitting diode 400 may generate light in the active layer 432. That is, since it is efficient that the lens layer 540 is disposed to cover only the active layer 432, the lens layer 540 may not cover the second electrode 420. Accordingly, among the plurality of optical lenses, the optical lens disposed inside the active layer 432 may not overlap with the second electrode 420. Alternatively, referring to FIG. 14, among the plurality of optical lenses, the optical lens disposed inside the active layer 432 may overlap with a portion of the second electrode 420.

Among the plurality of optical lens, the optical lens disposed inside the active layer 432 may have a length which is shorter than that of the optical lens disposed at the end of the active layer 432, but not limited thereto. Also, FIG. 14 discloses that one optical lens is disposed inside the active layer 432, but not limited thereto. That is, the plurality of optical lenses may be spaced apart from each other inside the active layer 432.

Referring to FIG. 15, each of the plurality of optical lenses may be formed to have a uniform height, but not limited thereto. In addition, referring to FIG. 16, a cross section of each of the plurality of optical lenses may have a semicircular shape, but not limited thereto.

According to the present disclosure, the scattering layer and the lens layer are formed on the light emitting diode so that it is possible to improve the light efficiency and the distribution of orientation angles in the display device.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A display device comprising:
a substrate with a plurality of subpixels;
at least one thin film transistor and at least one light emitting diode formed in each of the plurality of subpixels on the substrate; and
a molding portion formed on each of the light emitting diodes,
wherein the at least one thin film transistor and the at least one light emitting diode are electrically connected to each other, and
wherein the molding portion includes a scattering layer for scattering light and a lens layer formed on the scattering layer.

2. The display device according to claim 1, wherein the molding portion further includes first and second protective layers,
wherein the first protective layer is formed under the scattering layer and surrounds the light emitting diode, and
wherein the second protective layer is formed on the scattering layer and covers the lens layer.

3. The display device according to claim 2, wherein the molding portion further includes a light guide layer disposed between the scattering layer and the lens layer.

4. The display device according to claim 3, wherein the first protective layer and the scattering layer include a scattering material for scattering light and an insulating material.

5. The display device according to claim 2, wherein the molding portion further includes a light guide layer formed on a same layer as the scattering layer surrounding the light guide layer, and
wherein the lens layer overlaps with the light guide layer.

6. The display device according to claim 2, wherein the lens layer includes:
at least one optical lens;
a lower surface of the scattering layer is in contact with the light emitting diode; and
an upper surface of the scattering layer is in contact with the optical lens,
wherein the scattering layer is formed inside the optical lens.

7. The display device according to claim 2, wherein the light emitting diode includes first and second electrodes, a light emitting layer disposed on the first and second electrodes and an active layer, and
wherein the first protective layer exposes a portion of the first and second electrodes.

8. The display device according to claim 7, further comprising a common line formed under the light emitting diode, and the thin film transistor is formed under the light emitting diode,
wherein the first electrode is connected to the thin film transistor through a first connection electrode, and
wherein the second electrode is connected to the common line through a second connection electrode.

9. The display device according to claim 7, wherein the lens layer overlaps with the active layer.

10. The display device according to claim 9, wherein the lens layer includes at least one optical lens, and the optical lens has a convex hemispherical shape.

11. The display device according to claim 9, wherein the lens layer includes at least one optical lens that has a cross-section of a trapezoidal shape.

12. The display device according to claim 9, wherein the lens layer includes a plurality of optical lenses formed in a tunnel shape, and
wherein some of the plurality of optical lenses cover both ends of the active layer.

13. The display device according to claim 12, wherein, the optical lens disposed inside the active layer among the plurality of optical lens has a length shorter than that of the optical lens disposed at the both ends of the active layer.

14. A display device comprising:
a substrate with a plurality of subpixels;
at least one light emitting diode formed in each of the plurality of subpixels; and
a molding portion formed on each of the light emitting diodes,
wherein the molding portion includes a scattering layer for scattering light and a lens layer formed on the scattering layer, and
wherein the lens layer include a plurality of optical lenses which are arranged to extend along a first direction, are spaced apart from each other along a second direction perpendicular to the first direction, and are linearly formed.

15. The display device according to claim 14, wherein the molding portion further includes a light guide layer, and the light guide layer is formed between the scattering layer and the lens layer.

16. The display device according to claim 14, wherein the light emitting diode includes first and second electrodes spaced apart from each other in the first direction, and a light emitting layer formed on the first and second electrodes and configured to include an active layer, and the plurality of optical lenses are formed in a tunnel shape.

17. The display device according to claim 16, wherein among the plurality of optical lenses, two optical lenses disposed on the periphery may be formed to cover each of both ends of the active layer.
